(19) United States
(12) Patent Application Publication
(10) Pub. No.: US 2024/0206229 A1
(43) Pub. Date: Jun. 20, 2024

(54) DISPLAY APPARATUS

(71) Applicant: Samsung Display Co., Ltd., Yongin-si (KR)

(72) Inventors: Junyoung Min, Yongin-si (KR); Junyong An, Yongin-si (KR); Junwon Choi, Yongin-si (KR); Chulkyu Kang, Yongin-si (KR); Sujin Kim, Yongin-si (KR); Seonkyoon Mok, Yongin-si (KR)

(21) Appl. No.: 18/370,796

(22) Filed: Sep. 20, 2023

(30) Foreign Application Priority Data
Dec. 20, 2022 (KR) 10-2022-0179731

(51) Int. Cl. H10K 59/121; H10K 59/131

(52) U.S. Cl. CPC H10K 59/1213; H10K 59/1216; H10K 59/131

(57) ABSTRACT

A display apparatus includes: a substrate; a driving transistor over the substrate, and including a semiconductor layer including a driving active area; a driving voltage line between the substrate and the semiconductor layer, and extending in a first direction; a first capacitor including a first capacitor electrode at the same layer as that of the driving voltage line, and a second capacitor electrode at the same layer as that of the semiconductor layer; and a second capacitor including a third capacitor electrode at the same layer as that of the semiconductor layer, and a fourth capacitor electrode as a part of the driving voltage line.

### CROSS-REFERENCE TO RELATED APPLICATION

This application claims priority to and the benefit of Korean Patent Application No. 10-2022-0179731, filed on Dec. 20, 2022, in the Korean Intellectual Property Office, the entire disclosure of which is incorporated by reference herein.

### BACKGROUND

### 1. Field

One or more embodiments of the present disclosure relate to a display apparatus, and more particularly, to a display apparatus capable of displaying a high-quality image.

### 2. Description of the Related Art

Recently, display apparatuses have been used for various purposes. Also, as the thicknesses and weights of display apparatuses have decreased, the range of applications of the display apparatuses has increased.

As display apparatuses are widely used in a variety of ways, there may be various methods for designing the shapes of the display apparatuses. As an area where an image is displayed in a display apparatus increases, various functions linked to or associated with the display apparatus are being added.

In a display apparatus, thin-film transistors, connection electrodes, and wirings may be located in each sub-pixel to control a luminance and the like of each sub-pixel.

The above information disclosed in this Background section is for enhancement of understanding of the background of the present disclosure, and therefore, it may contain information that does not constitute prior art.

### SUMMARY

One or more embodiments of the present disclosure are directed to a display apparatus capable of displaying a high-quality image. However, the present disclosure is not limited thereto.

Additional aspects and features will be set forth, in part, in the description that follows, and in part, will be apparent from the description, or may be learned by practicing one or more of the presented embodiments.

According to one or more embodiments of the present disclosure, a display apparatus includes: a substrate; a driving transistor over the substrate, and including a semiconductor layer including a driving active area; a driving voltage line between the substrate and the semiconductor layer, and extending in a first direction; a first capacitor including a first capacitor electrode at the same layer as that of the driving voltage line, and a second capacitor electrode at the same layer as that of the semiconductor layer; and a second capacitor including a third capacitor electrode at the same layer as that of the semiconductor layer, and a fourth capacitor electrode as a part of the driving voltage line.

In an embodiment, an overlapping area between the first capacitor electrode and the second capacitor electrode may be greater than an overlapping area between the third capacitor electrode and the fourth capacitor electrode.

In an embodiment, the second capacitor electrode and the third capacitor electrode may be integral with each other.

In an embodiment, the display apparatus may further include: an interlayer insulating layer covering the driving transistor; and a first connection electrode on the interlayer insulating layer, and connecting the first capacitor electrode to a gate electrode of the driving transistor. The first connection electrode may be connected to the first capacitor electrode through a contact hole in an opening of the second capacitor electrode.

In an embodiment, the semiconductor layer may include an oxide semiconductor material.

In an embodiment, the display apparatus may further include a driving shield layer at the same layer as that of the driving voltage line, and overlapping with the driving active area.

In an embodiment, the display apparatus may further include: an interlayer insulating layer covering the driving transistor; and a second connection electrode on the interlayer insulating layer, and connecting the driving shield layer to the second capacitor electrode.

In an embodiment, the display apparatus may further include: a first scan line at the same layer as that of the driving voltage line, and extending in the first direction; and a switching transistor electrically connected to the first scan line, the switching transistor including: a lower switching gate electrode; a semiconductor layer including a switching active area; and an upper switching gate electrode. The lower switching gate electrode, the switching active area, and the upper switching gate electrode may be sequentially stacked, and the lower switching gate electrode may be a part of the first scan line.

In an embodiment, the display apparatus may further include: an interlayer insulating layer covering the driving transistor; and a data line and an additional line on the interlayer insulating layer, and extending in a second direction crossing the first direction.

In an embodiment, the second capacitor may further include a fifth capacitor electrode as a part of the additional line.

According to one or more embodiments of the present disclosure, a display apparatus includes: a substrate; a first sub-pixel on the substrate, and including a first pixel circuit including: a first driving transistor including a semiconductor layer; a 1-1^{th} capacitor; and a 1-2^{th} capacitor; a second sub-pixel on the substrate, and including a second pixel circuit including: a second driving transistor; a 2-1^{th} capacitor; and a 2-2^{th} capacitor; and a driving voltage line between the substrate and the semiconductor layer, the driving voltage line extending in a first direction, and electrically connected to the first sub-pixel and the second sub-pixel. The 1-2^{th} capacitor includes: a 1-3^{th} capacitor electrode at the same layer as that of the semiconductor layer; and a 1-4^{th} capacitor electrode as a part of the driving voltage line. The 2-2^{th} capacitor includes: a 2-3^{th} capacitor electrode at the same layer as that of the semiconductor layer; and a 2-4^{th} capacitor electrode as a part of the driving voltage line.

In an embodiment, a capacitance of the 1-2^{th} capacitor may be different from a capacitance of the 2-2^{th} capacitor.

In an embodiment, a capacitance of the 1-1^{th} capacitor may be greater than a capacitance of the 1-2^{th} capacitor.

In an embodiment, one electrode of the 1-1^{th} capacitor may be integral with one electrode of the 1-2^{th} capacitor.

In an embodiment, a driving gate electrode of the first driving transistor may be electrically connected to one electrode of the 1-1^{th} capacitor.

In an embodiment, the display apparatus may further include a driving shield layer at the same layer as that of the driving voltage line, and overlapping with the first driving transistor.

In an embodiment, the driving shield layer may be electrically connected to one electrode of the 1-1^{th} capacitor.

In an embodiment, the display apparatus may further include a first initialization line and a second initialization line at the same layer as that of the driving voltage line. The first initialization line may be connected to the first sub-pixel, and the second initialization line may be connected to the second sub-pixel.

In an embodiment, the display apparatus may further include: an interlayer insulating layer covering the first driving transistor and the second driving transistor; and a vertical initialization line on the interlayer insulating layer, and extending in a second direction crossing the first direction. The vertical initialization line may be connected to one of the first initialization line or the second initialization line through a contact hole.

In an embodiment, the display apparatus may further include: a third sub-pixel on the substrate, and including a third pixel circuit including: a third driving transistor; a 3-1^{th} capacitor; and a 3-2^{th} capacitor; an interlayer insulating layer covering the first driving transistor, the second driving transistor, and the third driving transistor; and an additional line on the interlayer insulating layer, and extending in a second direction crossing the first direction. One of the additional line may correspond to the first sub-pixel, the second sub-pixel, and the third sub-pixel.

In an embodiment, the 3-2^{th} capacitor may include a fifth capacitor electrode as a part of the additional line.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a plan view schematically illustrating a portion of a display apparatus, according to an embodiment;

FIG. 2 is a side view schematically illustrating the display apparatus of FIG. 1;

FIG. 3 is an equivalent circuit diagram illustrating a sub-pixel included in the display apparatus of FIG. 1;

FIG. 4 is a layout view schematically illustrating positions of transistors and capacitors in sub-pixels included in the display apparatus of FIG. 1;

FIGS. 5-8 are layout views schematically illustrating layers including elements such as transistors and capacitors of the display apparatus of FIG. 4;

FIG. 9 is a schematic cross-sectional view taken along the line I-I′ of the display apparatus of FIG. 4;

FIG. 10 is a cross-sectional view schematically illustrating a portion of a display apparatus, according to an embodiment; and

FIG. 11 is a layout view schematically illustrating some elements of sub-pixels included in a display apparatus, according to an embodiment.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

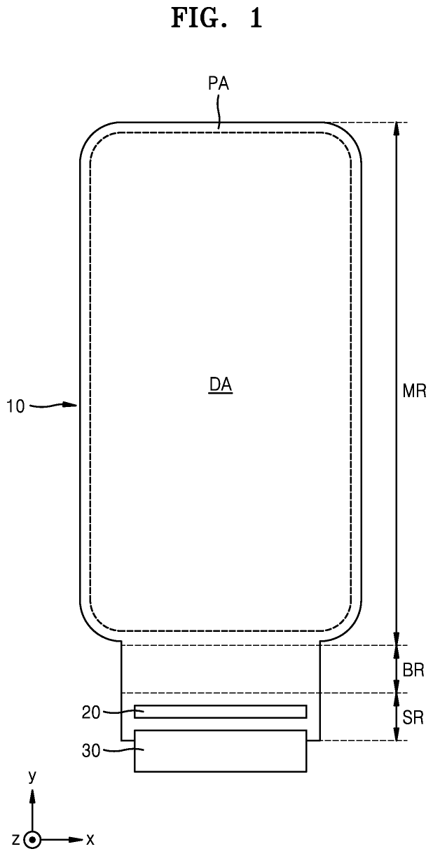

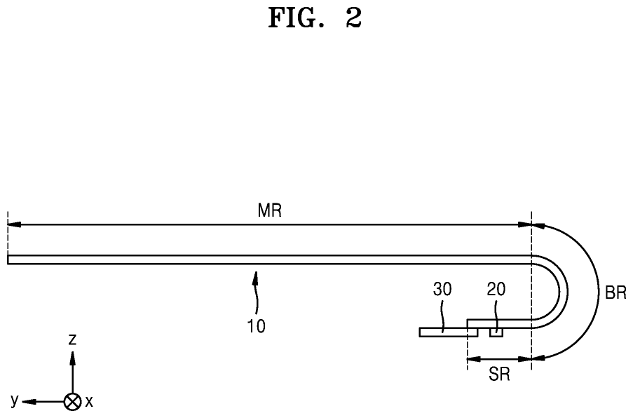

FIG. 1 is a plan view schematically illustrating a portion of a display apparatus, according to an embodiment. FIG. 2 is a side view schematically illustrating the display apparatus of FIG. 1. A portion of the display apparatus according to the present embodiment may be bent as shown in FIG. 2. However, for convenience, FIG. 1 shows that the display apparatus is not bent.

As shown in FIGS. 1 and 2, the display apparatus according to the present embodiment includes a display panel 10. The display apparatus may be any suitable apparatus, as long as the display apparatus includes a display panel 10. For example, the display apparatus may be any of various suitable products, such as a smartphone, a tablet, a laptop, a television, or a billboard.

The display panel 10 includes a display area DA, and a peripheral area PA outside the display area DA. The display area DA may be a portion where an image is displayed, and a plurality of pixels may be located in the display area DA. When viewed in a direction perpendicular to or substantially perpendicular to the display panel 10 (e.g., in a plan view), the display area DA may have any of various suitable shapes, such as a circular shape, an elliptical shape, a polygonal shape, or a shape of a specific figure. In FIG. 1, the display area DA has a rectangular or substantially rectangular shape with round corners.

The peripheral area PA may be located outside the display area DA. A width of a portion of the peripheral area PA (e.g., in the x-axis direction) may be less than a width of the display area DA (e.g., in the x-axis direction). Through this structure, at least a part of the peripheral area PA may be easily bent as described in more detail below.

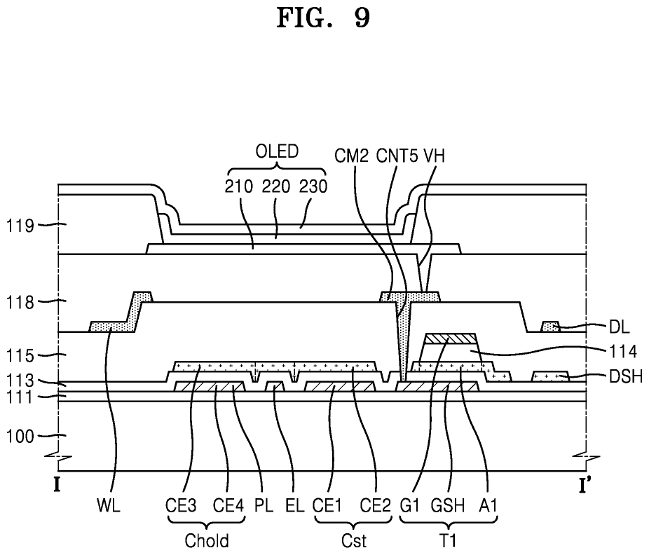

Because the display panel 10 includes a substrate 100 (e.g., see FIG. 9), the substrate 100 may include the display area DA and the peripheral area PA. For convenience, the following will be described in the context in which the substrate 100 includes the display area DA and the peripheral area PA.

The display panel 10 may include a main area MR, a bending area BR outside the main area MR, and a sub-area SR located opposite to the main area MR with the bending area BR therebetween. In the bending area BR, the display panel 10 is bent as shown in FIG. 2, so that at least a part of the sub-area SR may overlap with the main area MR when viewed in the z-axis direction. However, the present disclosure is not limited to a display apparatus that is bent, and may be applied to a display apparatus that is not bent. The sub-area SR may be a non-display area as described in more detail below. As the display panel 10 is bent in the bending area BR, when the display apparatus is viewed from a front surface (e.g., in the -z direction), the non-display area may not be visible, but even when visible, a visible area thereof may be minimized or reduced.

A driving chip 20 may be located in the sub-area SR of the display panel 10. The driving chip 20 may include an integrated circuit that drives the display panel 10. The integrated circuit may be, but is not limited to, a data driving integrated circuit that generates a data signal.

The driving chip 20 may be mounted in the sub-area SR of the display panel 10. Although the driving chip 20 is mounted on the same surface as that of a display surface of the display area DA, because the display panel 10 is bent in the bending area BR as described above, the driving chip 20 may be located on the rear surface of the main area MR.

A printed circuit board 30 or the like may be attached to an end of the sub-area SR of the display panel 10. The printed circuit board 30 or the like may be electrically connected to the driving chip 20 or the like through a pad on the substrate.

Hereinafter, although an organic light-emitting display apparatus is described as the display apparatus according to an embodiment, the present disclosure is not limited thereto. In another embodiment, the display apparatus may be an inorganic light-emitting display apparatus or an inorganic electroluminescent (EL) display apparatus, or a quantum dot light-emitting display. For example, an emission layer of a display device included in the display apparatus may include an organic material or an inorganic material. The display apparatus may include an emission layer, and a quantum dot layer located in a path of light emitted from the emission layer.

A plurality of pixels are located in the display area DA. Each of the pixels may include a plurality of sub-pixels, and each of the sub-pixels may include a display device, such as an organic light emitting diode OLED. Each sub-pixel may emit, for example, such as red light, green light, blue light, or white light.

Each sub-pixel may be electrically connected to outer circuits located in the peripheral area PA. A scan driving circuit, an emission control driving circuit, a terminal, a first power supply wiring, and a second power supply wiring may be located in the peripheral area PA. The scan driving circuit may provide a scan signal to a pixel through a scan line. The emission control driving circuit may provide an emission control signal to a pixel through an emission control line. The terminal located in the peripheral area PA may be exposed without being covered by an insulating layer, and may be electrically connected to the printed circuit board 30. A terminal of the printed circuit board 30 may be electrically connected to a terminal of the display panel 10.

The printed circuit board 30 transmits a signal or power of a controller to the display panel 10. A control signal generated by the controller may be transmitted to the driving circuits through the printed circuit board 30. Also, the controller may provide a driving power supply voltage ELVDD (e.g., a driving voltage) to the first power supply wiring, and may provide a common power supply voltage ELVSS to the second power supply wiring.

The controller may generate a data signal, and the generated data signal may be transmitted to a sub-pixel through the driving chip 20 and a data line.

For reference, a “line” may refer to a “wiring”. This also applies to the following embodiments and modifications thereof.

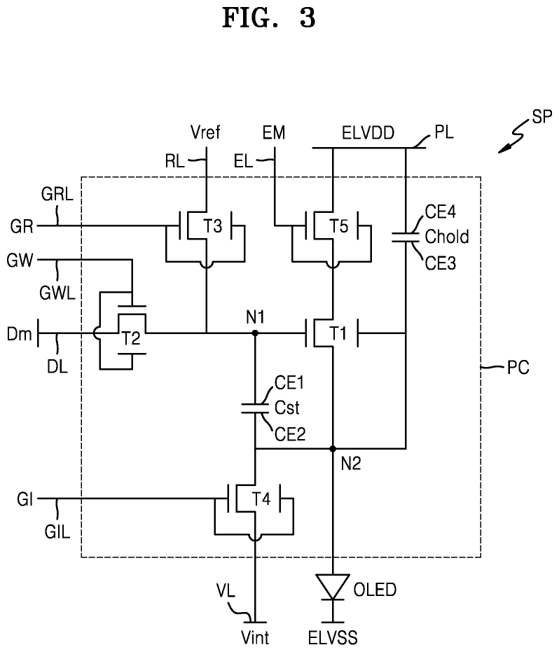

FIG. 3 is an equivalent circuit diagram illustrating a sub-pixel SP included in the display apparatus of FIG. 1. As shown in FIG. 3, one sub-pixel SP may include a pixel circuit PC, and an organic light-emitting diode OLED electrically connected to the pixel circuit PC.

The pixel circuit PC may include a plurality of thin-film transistors (e.g., T1 to T5), a first capacitor Cst, and a second capacitor Chold, as shown in FIG. 3. The plurality of thin-film transistors (e.g., T1 to T5), the first capacitor Cst, and the second capacitor Chold may be connected to signal lines (e.g., GWL, GRL, GIL, EL, and DL), an initialization voltage line VL, a reference voltage line RL, and a driving voltage line PL.

The plurality of thin-film transistors (e.g., T1 to T5) may include a driving transistor T1, a switching transistor T2, a reference voltage transistor T3, an initialization transistor T4, and an emission control transistor T5.

The organic light emitting diode OLED may include a pixel electrode 210 and a counter electrode 230 (e.g., see FIG. 9). The pixel electrode 210 of the organic light emitting diode OLED may be connected to the driving transistor T1 to receive a driving current, and the counter electrode 230 may receive the common power supply voltage ELVSS. The organic light-emitting diode OLED may generate light having a luminance corresponding to the driving current.

The plurality of thin-film transistors (e.g., T1 to T5) may be n-channel MOSFETs (NMOSs). The plurality of thin-film transistors T1 to T5 may include an oxide semiconductor material.

The signal lines may include a first scan line GWL that transmits a first scan signal GW, a second scan line GRL that transmits a second scan signal GR, a third scan line GIL that transmits a third scan signal GI, an emission control signal line EL that transmits an emission control signal EM, and a data line DL that crosses the first scan line GWL and transmits a data signal Dm.

The initialization voltage line VL may transmit an initialization voltage Vint that initializes the pixel electrode of the organic light emitting diode OLED. The reference voltage line RL may transmit a reference voltage Vref to a gate electrode of the driving transistor T1. The driving voltage line PL may transmit a driving power supply voltage ELVDD that is a driving voltage to the driving transistor T1.

A driving gate electrode of the driving transistor T1 may be connected to the first capacitor Cst through a first node N1, a drain region of the driving transistor T1 may be connected to the driving voltage line PL via the emission control transistor T5, and a source region of the driving transistor T1 may be electrically connected to the pixel electrode 210 of the organic light emitting diode OLED through a second node N2. The driving transistor T1 may receive the data signal Dm according to a switching operation of the switching transistor T2, and may supply a driving current to the organic light-emitting diode OLED. In other words, the driving transistor T1 may control the amount of current flowing through the organic light emitting diode OLED in response to a voltage applied to the first node N1, which varies according to the data signal Dm.

A switching gate electrode of the switching transistor T2 may be connected to the first scan line GWL that transmits the first scan signal GW, any one of a source region or a drain region of the switching transistor T2 may be connected to the data line DL, and the other of the source region or the drain region of the switching transistor T2 may be connected to the driving gate electrode of the driving transistor T1 through the first node N1. The switching transistor T2 may transmit the data signal Dm from the data line DL to the first node N1, in response to a voltage applied to the first scan line GWL. In other words, the switching transistor T2 may be turned on according to the first scan signal GW received through the first scan line GWL, and may perform a switching operation of transmitting the data signal Dm transmitted through the data line DL to the driving transistor T1 through the first node N1.

A reference voltage gate electrode of the reference voltage transistor T3 may be connected to the second scan line GRL that transmits the second scan signal GR, any one of a source electrode or a drain electrode of the reference voltage transistor T3 may be connected to the reference voltage line RL, and the other of the source electrode or the drain electrode of the reference voltage transistor T3 may be connected to the driving gate electrode of the driving transistor T1 through the first node N1. The reference voltage transistor T3 may transmit the reference voltage Vref from the reference voltage line RL to the first node N1, in response to a voltage applied to the second scan line GRL. When necessary or desired, the second scan line GRL may be the first scan line GWL of a sub-pixel belonging to a previous row that is adjacent to the sub-pixel SP of FIG. 3, and electrically connected to the same data line DL. In this case, the second scan signal GR may be a previous writing signal (e.g., a previous scan signal).

An initialization gate electrode of the initialization transistor T4 may be connected to the third scan line GIL, any one of a source region or a drain region of the initialization transistor T4 may be connected to the pixel electrode 210 of the organic light emitting diode OLED through the second node N2, and the other of the source region or the drain region of the initialization transistor T4 may be connected to the initialization voltage line VL to receive the initialization voltage Vint. The initialization transistor T4 is turned on according to the third scan signal GI received through the third scan line GIL, and initializes the pixel electrode 210 of the organic light emitting diode OLED. When necessary or desired, the third scan line GIL may be the first scan line GWL of a sub-pixel belonging to a next row that is adjacent to the sub-pixel SP of FIG. 3, and electrically connected to the same data line DL. In this case, the third scan signal GI may be a next writing signal (e.g., a next scan signal).

An operation control gate electrode of the emission control transistor T5 may be connected to the emission control line EL, any one of a source region or a drain region of the emission control transistor T5 may be connected to the driving voltage line PL, and the other may be connected to the drain region of the driving transistor T1. The emission control transistor T5 is turned on according to the emission control signal EM received through the emission control line EL, and the driving power supply voltage ELVDD may be transmitted to the organic light emitting diode OLED, so that a driving current flows through the organic light emitting diode OLED.

The first capacitor Cst that is a storage capacitor may include a first capacitor electrode CE1 and a second capacitor electrode CE2. The first capacitor electrode CE1 of the first capacitor Cst is connected to the driving gate electrode of the driving transistor T1 through the first node N1, and the second capacitor electrode CE2 of the first capacitor Cst is connected to the source region of the driving transistor T1 through the second node N2. The first capacitor Cst may store a charge corresponding to a difference between a driving gate electrode voltage of the driving transistor T1 and the initialization voltage Vint.

The second capacitor Chold that is a holding capacitor may include a third capacitor electrode CE3 and a fourth capacitor electrode CE4. The third capacitor electrode CE3 of the second capacitor Chold may be connected to the source region of the driving transistor T1 through the second node N2, and the fourth capacitor electrode CE4 of the second capacitor Chold may be connected to the driving voltage line PL. A compensation voltage for compensating for a threshold voltage Vth of the driving transistor T1 may be stored in the second capacitor Chold.

An operation of each sub-pixel SP according to an embodiment is described in more detail as follows.

During an initialization period, when the third scan signal GI is supplied through the third scan line GIL, the initialization transistor T4 is turned on, and the pixel electrode 210 of the organic light emitting diode OLED is initialized by the initialization voltage Vint supplied from the initialization voltage line VL. The source region of the driving transistor T1 electrically connected to the pixel electrode 210 of the organic light emitting diode OLED through the second node N2, and the third capacitor electrode CE3 of the second capacitor Chold are also initialized. As described above, the third scan line GIL may be the first scan line GWL in a sub-pixel belonging to a next row adjacent to the sub-pixel SP of FIG. 3, and electrically connected to the same data line DL. In this case, the third scan signal GI may be a next writing signal (e.g., a next scan signal).

During a compensation period, when the second signal GR is supplied through the second scan line GRL, the reference voltage transistor T3 is turned on, and the reference voltage Vref supplied from the reference voltage line RL is transmitted to the gate electrode G1 of the driving transistor T1 to compensate for the threshold voltage Vth of the driving transistor T1. A compensation voltage for compensating for the threshold voltage Vth of the driving transistor T1 is stored in the second capacitor Chold. As described above, when necessary or desired, the second scan line GRL may be the first scan line GWL in a sub-pixel belonging to a previous row adjacent to the sub-pixel SP of FIG. 3, and electrically connected to the same data line DL. In this case, the second scan signal GR may be a previous writing signal (e.g., a previous scan signal).

During a data programming period, when the first scan signal GW is supplied through the first scan line GWL, the switching transistor T2 is turned on in response to the first scan signal GW. A voltage corresponding to the data signal Dm supplied from the data line DL is applied to the driving gate electrode of the driving transistor T1. Because the first capacitor electrode CE1 of the first capacitor Cst is connected to the driving gate electrode of the driving transistor T1 through the first node N1, and the second capacitor electrode CE2 of the first capacitor Cst is connected to the third capacitor electrode of the second capacitor Chold storing a compensation voltage for compensating for the threshold voltage Vth of the driving transistor T1 through the second node N2, a data voltage obtained by compensating for the threshold voltage Vth of the driving transistor T1 is stored in the first capacitor Cst.

During an emission period, the emission control transistor T5 is turned on by the emission control signal EM supplied from the emission control line EL. Because the first capacitor electrode CE1 of the first capacitor Cst is connected to the driving gate electrode of the driving transistor T1 through the first node N1, and the second capacitor electrode CE2 of the first capacitor Cst is connected to the source region of the driving transistor T1 through the second node N2, a driving current corresponding to the data signal Dm flows through the organic light emitting diode OLED regardless of the threshold voltage Vth of the driving transistor T1, due to the data voltage obtained by compensating for the threshold voltage Vth of the driving transistor T1 stored in the first capacitor Cst.

As described above, the plurality of thin-film transistors (e.g., T1 to T5) may include an oxide semiconductor material. Because an oxide semiconductor has high carrier mobility and low leakage current, a voltage drop may not be large even when a driving time is long. In other words, in the case of an oxide semiconductor, because a color change in an image due to the voltage drop may not be large even during low-frequency driving, low-frequency driving is possible. Accordingly, because the plurality of thin-film transistors (e.g., T1 to T5) include an oxide semiconductor material, the display apparatus in which a leakage current is prevented or reduced, and power consumption is reduced may be implemented.

Because an oxide semiconductor is sensitive to light, the amount of current or the like may be changed by external light. Accordingly, it may be considered to locate a metal layer under the oxide semiconductor to absorb or reflect external light. Accordingly, as shown in FIG. 3, each of the switching transistor T2, the reference voltage transistor T3, the initialization transistor T4, and the emission control transistor T5 including an oxide semiconductor layer may include a gate electrode located over and under the oxide semiconductor layer. Also, even in the case of the driving transistor T1, a metal layer may be located under an oxide semiconductor layer. In other words, when viewed in a direction (e.g., the z-axis direction) perpendicular to a top surface of the substrate 100 (e.g., in a plan view), a metal layer located under an oxide semiconductor may overlap with the oxide semiconductor.

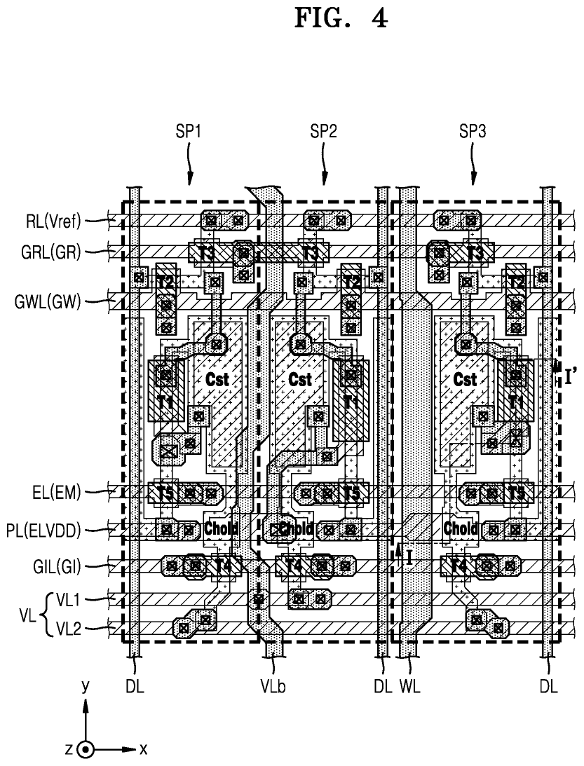

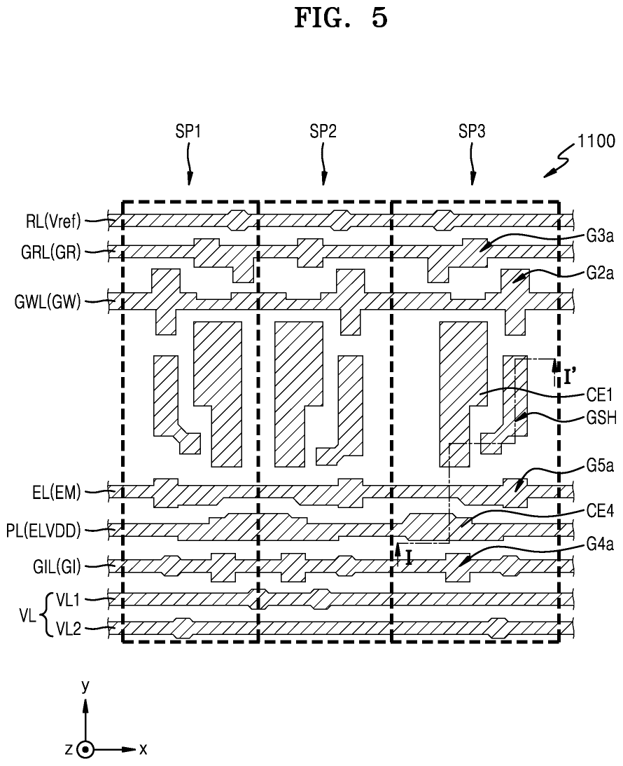

FIG. 4 is a layout view schematically illustrating positions of transistors and capacitors in sub-pixels included in the display apparatus of FIG. 1. For example, FIG. 4 illustrates the thin-film transistors (e.g., T1 to T5), the first capacitor Cst, and the second capacitor Chold in the pixels included in the display apparatus of FIG. 1. FIGS. 5 through 8 are layout views schematically illustrating layers including elements such as transistors and capacitors of the display apparatus of FIG. 4. For example, FIGS. 5 through 8 illustrate the layers including the thin-film transistors (e.g., T1 to T5), the first capacitor Cst, and the second capacitor Chold of the display apparatus of FIG. 4. FIG. 9 is a schematic cross-sectional view taken along the line I-I′ of the display apparatus of FIG. 4.

As shown in FIGS. 4 to 8, the display apparatus may include the pixels, and each of the pixels may include a first sub-pixel SP1, a second sub-pixel SP2, and a third sub-pixel SP3. For example, the first sub-pixel SP1 may be a red sub-pixel for emitting red light, the second sub-pixel SP2 may be a green sub-pixel for emitting green light, and the third sub-pixel SP3 may be a blue sub-pixel for emitting blue light. However, the present disclosure is not limited thereto, and one pixel may include fewer or more sub-pixels.

A structure as shown in FIGS. 4 to 8 may be repeatedly located in a first direction (e.g., the x-axis direction) and/or a second direction (e.g., the y-axis direction).

Each of the first sub-pixel SP1 to the third sub-pixel SP3 may include a pixel circuit. For convenience of illustration, some elements will be described in more detail based on the pixel circuit of the third sub-pixel SP3, but the elements may also be located in the pixel circuit of each of the first sub-pixel SP1 and the second sub-pixel SP2.

The substrate 100 (e.g., see FIG. 9) may have a single-layer structure formed of a glass material. As another example, the substrate 100 may include a polymer resin. The substrate 100 including the polymer resin may have a structure in which a layer including a polymer resin and an inorganic layer are stacked. In an embodiment, the substrate 100 may include the polymer resin, such as polyethersulfone, polyarylate, polyether imide, polyethylene naphthalate, polyethylene terephthalate, polyphenylene sulfide, polyimide, polycarbonate, cellulose triacetate, and/or cellulose acetate propionate, and may be flexible. The substrate 100 may include glass having SiO₂ as a main component, or may include a suitable resin, such as reinforced plastic, and may be rigid.

A first buffer layer 111 (e.g., see FIG. 9) including silicon oxide, silicon nitride, or silicon oxynitride may be located on the substrate 100. The first buffer layer 111 may planarize or substantially planarize a top surface of the substrate 100.

A lower metal layer 1100 as shown in FIG. 5 may be located on the first buffer layer 111. The lower metal layer 1100 may include the reference voltage line RL that transmits the reference voltage Vref, the second scan line GRL that transmits the second scan signal GR, the first scan line GWL that transmits the first scan signal GW, the emission control signal line EL that transmits the emission control signal EM, the driving voltage line PL that transmits the driving power supply voltage ELVDD, the third scan line GIL that transmits the third scan signal GI, the initialization voltage line VL that transmits the initialization voltage Vint, the first capacitor electrode CE1, the fourth capacitor electrode CE4, and a driving shield layer GSH.

From among the lower metal layer 1100, the reference voltage line RL, the second scan line GRL, the first scan line GWL, the emission control signal line EL, the driving voltage line PL, the third scan line GIL, and the initialization voltage line VL may extend in the first direction (e.g., the x-axis direction).

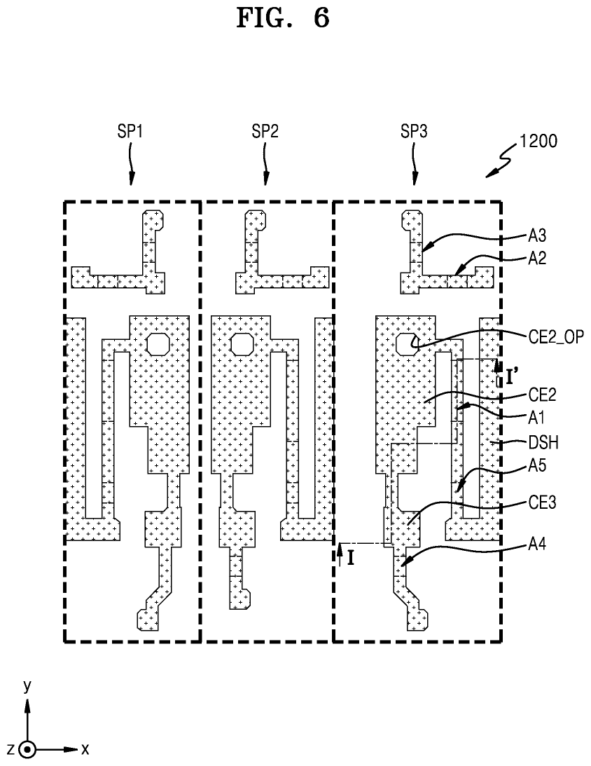

Parts of the first scan line GWL, the second scan line GRL, the third scan line GIL, and the emission control signal line EL may overlap with a semiconductor layer 1200 (e.g., see FIG. 6), and may function as gate electrodes.

A portion of the first scan line GWL overlapping with the semiconductor layer 1200 may be a lower switching gate electrode G2a of the switching transistor T2. In FIG. 5, the first scan line GWL may have a protrusion in a +y direction, and the protrusion may be the lower switching gate electrode G2a.

A portion of the second scan line GRL overlapping with the semiconductor layer 1200 may be a lower reference voltage gate electrode G3a of the reference voltage transistor T3. In FIG. 5, the second scan line GRL has a protrusion in the +y direction and a −y direction, and the protrusion may be the lower reference voltage gate electrode G3a.

A portion of the third scan line GIL overlapping with the semiconductor layer 1200 may be a lower initialization gate electrode G4a of the initialization transistor T4. In FIG. 5, the third scan line GIL has a protrusion in the +y direction and the -y direction, and the protrusion may be the lower initialization gate electrode G4a.

A portion of the emission control line EL overlapping with the semiconductor layer 1200 may be a lower reference voltage gate electrode G5a of the emission control transistor T5. In FIG. 5, the emission control line EL has a protrusion in the +y direction and the −y direction, and the protrusion may be the lower emission control gate electrode G5a.

A portion of the driving voltage line PL overlapping with the semiconductor layer 1200 may be the fourth capacitor electrode CE4 of the second capacitor Chold. The fourth capacitor electrode CE4 may overlap with the third capacitor electrode CE3 provided as the semiconductor layer 1200 (e.g., a portion thereof), to form the second capacitor Chold.

The initialization voltage line VL may include a first initialization voltage line VL1 and a second initialization voltage line VL2. The first initialization voltage line VL1 may transmit an initialization voltage to the second sub-pixel SP2. The second initialization voltage line VL2 may transmit an initialization voltage to the first sub-pixel SP1 and the third sub-pixel SP3.

The first capacitor electrode CE1 may have an isolated shape. The first capacitor electrode CE1 that is one electrode of the first capacitor Cst of FIG. 3 may overlap with the second capacitor electrode CE2 provided as the semiconductor layer 1200 (e.g., a portion thereof) to form the first capacitor Cst. An area of the first capacitor electrode CE1 may be greater than an area of the fourth capacitor electrode CE4.

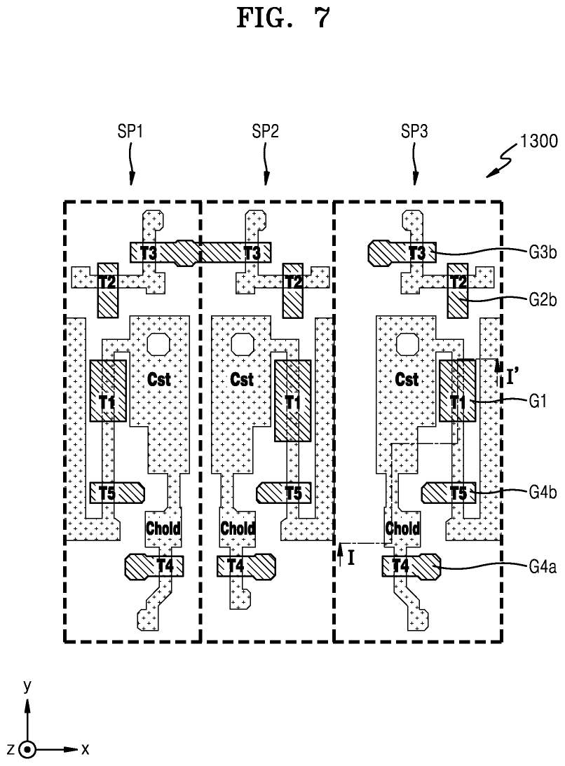

The driving shield layer GSH may have an isolated shape, like that of the first capacitor electrode CE1. The driving shield layer GSH may overlap with the driving gate electrode G1 (e.g., see FIG. 7) and a driving active area A1 (e.g., see FIG. 6) described in more detail below, and thus, may prevent, minimize, or reduce external light from being incident on the driving active area A1. In addition, the driving shield layer GSH may be electrically connected to the second capacitor electrode CE2 (e.g., see FIG. 6) through a second connection electrode CM2 (e.g., see FIG. 9) described in more detail below. Accordingly, because a voltage stored in the first capacitor Cst is applied to the driving shield layer GSH, the driving shield layer GSH may protect the driving active area A1 from an unintended electrical signal from the outside. The driving shield layer GSH may be a lower driving gate electrode.

Similarly, the lower switching gate electrode G2a, the lower reference voltage gate electrode G3a, the lower initialization gate electrode G4a, and the lower operation control gate electrode G5a may overlap with a switching active area A2, a reference voltage active area A3, an initialization active area A4, and an emission control active area A5 located thereover, and thus, external light may be prevented, minimized, or reduced from being incident on these active areas.

The lower metal layer 1100 may include a metal, an alloy, or a conductive metal oxide. For example, the lower metal layer 1100 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), or scandium (Sc). The lower metal layer 1100 may have a multi-layered structure.

A second buffer layer 113 (e.g., see FIG. 9) may cover the lower metal layer 1100, and may be located on the substrate 100. The second buffer layer 113 may include an insulating material. For example, the second buffer layer 113 may include silicon oxide, silicon nitride, or silicon oxynitride. The second buffer layer 113 may prevent or substantially prevent metal atoms or impurities from being diffused from the substrate 100 or the like to the semiconductor layer 1200 over the substrate 100.

The semiconductor layer 1200 as shown in FIG. 6 may be located on the second buffer layer 113. As described above, the semiconductor layer 1200 may include an oxide semiconductor material. For example, the semiconductor layer 1200 may include ITGZO having a thickness of about 300 Å. The driving transistor T1, the switching transistor T2, the reference voltage transistor T3, the initialization transistor T4, the emission control transistor T5, the first capacitor Cst, and the second capacitor Chold are located along the semiconductor layer 1200 as shown in FIG. 6.

In FIG. 6, the semiconductor layer 1200 is shown as including a first portion and a second portion that are spaced apart from each other. The switching active area A2 of the switching transistor T2 and the reference voltage active area A3 of the reference voltage transistor T3 are located in the first portion, and the driving active area A1 of the driving transistor T1, the initialization active area A4 of the initialization transistor T4, the emission control active area A5 of the emission control transistor T5, the second capacitor electrode CE2, the third capacitor electrode CE3, and a data shield layer DSH are located in the second portion.

The second capacitor electrode CE2 may include an opening CE2_OP having a closed shape. A first connection electrode CM1 described in more detail below may be connected to the first capacitor electrode CE1 through the opening CE2_OP. The second capacitor electrode CE2 and the third capacitor electrode CE3 may be integrally formed with each other. An area of the second capacitor electrode CE2 may be greater than an area of the third capacitor electrode CE3.

In the present embodiment, a capacitance of the first capacitor Cst may be greater than a capacitance of the second capacitor Chold. In other words, an overlapping area between the first capacitor electrode CE1 and the second capacitor electrode CE2 may be greater than an overlapping area between the third capacitor electrode CE3 and the fourth capacitor electrode CE4.

The data shield layer DSH may overlap with the data line DL described in more detail below. The data shield layer DSH may prevent, minimize, or reduce other transistors from being affected by a data signal provided to the data line DL. The data shield layer DSH may extend by a suitable length (e.g., a certain or predetermined length) in the second direction (e.g., the y-axis direction).

A gate insulating layer 114 (e.g., see FIG. 9) may be located on the semiconductor layer 1200. The gate insulating layer 114 may include an insulating material. For example, the gate insulating layer 114 may include an inorganic insulating layer, such as silicon oxide, silicon nitride, silicon oxynitride, or aluminum oxide. The gate insulating layer 114 may have a multi-layered structure of the inorganic insulating layer. The gate insulating layer 114 may be patterned along a shape of a first conductive layer 1300 (e.g., see FIG. 7) located over the gate insulating layer 114.

The first conductive layer 1300 as shown in FIG. 7 may be located on the gate insulating layer 114. In FIG. 7, for convenience, the first conductive layer 1300 is illustrated together with the semiconductor layer 1200. The first conductive layer 1300 may include the driving gate electrode G1, an upper switching gate electrode G2b, an upper reference voltage gate electrode G3b, an upper initialization gate electrode G4b, and an upper emission control gate electrode G5b. The first conductive layer 1300 may be a gate layer.

The driving gate electrode G1 may overlap with the driving active area A1 of the semiconductor layer 1200. Also, the driving gate electrode G1 may overlap with the driving shield layer GSH of the lower metal layer 1100.

The upper switching gate electrode G2b may overlap with the switching active area A2 of the semiconductor layer 1200. The upper switching gate electrode G2b may function as a gate electrode of the switching transistor T2, together with the lower switching gate electrode G2a that is electrically connected to the upper switching gate electrode G2b.

The upper reference voltage gate electrode G3b may overlap with the reference voltage active area A3 of the semiconductor layer 1200. The upper reference voltage gate electrode G3b may function as a gate electrode of the reference voltage transistor T3, together with the lower reference voltage gate electrode G3a that is electrically connected to the upper reference voltage gate electrode G3b. In some embodiments, the upper reference voltage gate electrodes G3b located in adjacent sub-pixels may be integrally provided with each other. In FIG. 7, the upper reference voltage gate electrode G3b of the first sub-pixel SP1 and the upper reference voltage gate electrode G3b of the second sub-pixel SP2 are integrally provided with each other.

The upper initialization gate electrode G4b may overlap with the initialization active area A4 of the semiconductor layer 1200. The upper initialization gate electrode G4b may function as a gate electrode of the initialization transistor T4, together with the lower initialization gate electrode G4a that is electrically connected to the upper initialization gate electrode G4b.

The upper emission control gate electrode G5b may overlap with the emission control active area A5 of the semiconductor layer 1200. The upper emission control gate electrode G5b may function as a gate electrode of the emission control transistor T5, together with the lower emission control gate electrode G5a that is electrically connected to the upper emission control gate electrode G5b.

The first conductive layer 1300 may include a metal, an alloy, a conductive metal oxide, or a transparent conductive material. For example, the first conductive layer 1300 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). The first conductive layer 1300 may have a multi-layered structure.

An interlayer insulating layer 115 (e.g., see FIG. 9) may cover the first conductive layer 1300, and may be located on the substrate 100. The interlayer insulating layer 115 may include an insulating material. For example, the interlayer insulating layer 115 may include silicon oxide, silicon nitride, silicon oxynitride, or aluminum oxide.

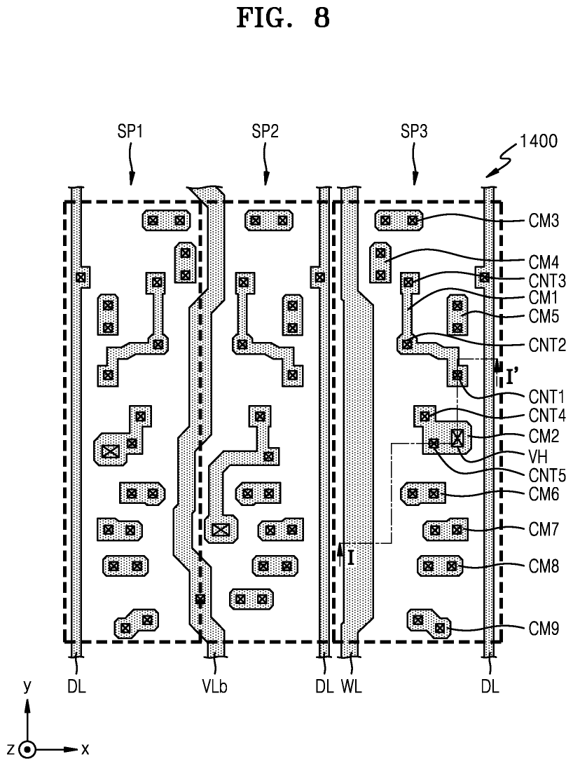

A second conductive layer 1400 as shown in FIG. 8 may be located on the interlayer insulating layer 115. The second conductive layer 1400 may include the data line DL, a vertical initialization line VLb, an additional line WL, and the first and second connection electrodes CM1 and CM2. From among the second conductive layer 1400, the data line DL, the vertical initialization line VLb, and the additional line WL may extend in or substantially in the second direction (e.g., the y-axis direction). The second conductive layer 1400 may be a source/drain layer.

A corresponding data line DL may be located in each of the first to third sub-pixels SP1, SP2, and SP3. The data line DL may be connected to a side of the switching active area A2 of the semiconductor layer 1200 under the data line DL through a contact hole.

The vertical initialization line VLb may not be located in each of the first to third sub-pixels SP1, SP2, and SP3, and one vertical initialization line VLb may be located across the first to third sub-pixel SP1, SP2, and SP3. The vertical initialization line VLb may be connected to the initialization voltage line VL of the lower metal layer 1100 under the vertical initialization line VLb through a contact hole. In the drawings, the vertical initialization line VLb is connected to the first initialization voltage line VL1. The additional line WL may not be located in each of the first to third sub-pixels SP1, SP2, and SP3, and one additional line WL may be located across the first to third sub-pixels SP1, SP2, and SP3. The additional line WL may function as a vertical driving voltage line that transmits the driving power supply voltage ELVDD, or may function as a common voltage line that transmits the common voltage ELVSS.

The first connection electrode CM1 is connected to the driving gate electrode G1 through a contact hole CNT1. The first connection electrode CM1 is connected to the first capacitor electrode CE1 through a contact hole CNT2 passing through the opening CE2_OP of the second capacitor electrode CE2 of the first capacitor Cst. In other words, the first connection electrode CM1 electrically connects the first capacitor electrode CE1 of the first capacitor Cst to the driving gate electrode G1 of the driving transistor T1. Also, the first connection electrode CM1 may be connected between a side of the reference voltage active are A3 and a side of the switching active area A2 through a contact hole CNT3. The first connection electrode CM1 may function as the first node N1 of FIG. 3.

The second connection electrode CM2 is connected to the second capacitor electrode CE2 of the first capacitor Cst through a contact hole CNT4. The second connection electrode CM2 is connected to the driving shield layer GSH through a contact hole CNT5. Also, the pixel electrode 210 of the organic light emitting diode OLED described in more detail below may be connected to the second connection electrode CM2 through a via hole VH. In other words, the second connection electrode CM2 electrically connects the organic light emitting diode OLED, the first capacitor Cst, and the driving transistor T1 to each other. The second connection electrode CM2 may function as the second node N2 of FIG. 3.

A third connection electrode CM3 may connect the reference voltage line RL to a side of the reference voltage active area A3 through contact holes. A fourth connection electrode CM4 may connect the second scan line GRL to the upper reference voltage gate electrode G3b through contact holes. A fifth connection electrode CM5 may connect the first scan line GWL to the upper switching gate electrode G2b through contact holes. A sixth connection electrode CM6 may connect the emission control line EL to the upper emission control gate electrode G5b through contact holes. A seventh connection electrode CM7 may connect the driving voltage line PL to a side of the emission control active area A5 through contact holes. An eighth connection electrode CM8 may connect the third scan line GIL to the upper initialization gate electrode G4b through contact holes. A ninth connection electrode CM9 may connect the initialization voltage line VL to a side of the initialization active layer A4 through contact holes.

The second conductive layer 1400 may include a metal, an alloy, a conductive metal oxide, or a transparent conductive material. For example, the second conductive layer 1400 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). The second conductive layer 1400 may have a multi-layered structure.

A via layer 118 (e.g., see FIG. 9) may cover the second conductive layer 1400, and may be located on the interlayer insulating layer 115. The via layer 118 may include an organic insulating material. For example, the via layer 118 may include a photoresist, benzocyclobutene (BCB), polyimide, hexamethyldisiloxane (HMDSO), polymethylmethacrylate (PMMA), polystyrene (PS), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a suitable blend thereof. For example, the via layer 118 may include a polyimide layer having a thickness of about 1.6 μm.

The organic light emitting diode OLED may be located on the via layer 118. The organic light-emitting diode OLED may include the pixel electrode 210, an intermediate layer 220 including an emission layer, and the counter electrode 230.

The pixel electrode 210 may be a (semi-)transmissive electrode or a reflective electrode. For example, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a suitable compound thereof, and a transparent or semi-transparent electrode layer located on the reflective layer. The transparent or semi-transparent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). For example, the pixel electrode 210 may have a three-layered structure including ITO/Ag/ITO.

A pixel-defining film 119 may be located on the via layer 118. The pixel-defining film 119 may increase a distance between an edge of the pixel electrode 210 and the counter electrode 230 over the pixel electrode 210, to prevent or substantially prevent an arc or the like from occurring on the edge of the pixel electrode 210. The pixel-defining film 119 may be formed of at least one organic insulating material selected from the group consisting of polyimide, polyamide, an acrylic resin, benzocyclobutene, and a phenolic resin, by using spin coating or the like.

At least a part of the intermediate layer 220 of the organic light emitting diode OLED may be located in an opening formed by the pixel-defining film 119. An emission area of the organic light emitting diode OLED may be defined by the opening.

The intermediate layer 220 may include an emission layer. The emission layer may include an organic material including a fluorescent or phosphorescent material that emits red, green, blue, or white light. The emission layer may be formed of a low molecular weight organic material or a high molecular weight organic material, and one or more functional layers, such as a hole transport layer (HTL), a hole injection layer (HIL), an electron transport layer (ETL), and/or an electron injection layer (EIL), may be selectively located under and/or over the emission layer.

The emission layer may have a shape that is patterned to correspond to each of the pixel electrodes 210. The layers other than the emission layer of the intermediate layer 220 may be variously modified as needed or desired, for example, such as being integrally formed over a plurality of the pixel electrodes 210.

The counter electrode 230 may be a light-transmitting electrode or a reflective electrode. For example, the counter electrode 230 may be a transparent or semi-transparent electrode, and may include a metal thin film having a low work function including lithium (Li), calcium (Ca), LiF, aluminum (Al), silver (Ag), magnesium (Mg), or a suitable compound thereof. Also, the counter electrode 230 may further include a transparent conductive oxide (TCO) film, such as ITO, IZO, ZnO, or In₂O₃, located on the metal thin film. The counter electrode 230 may be integrally formed over an entire surface of the display area DA, and may be located on the intermediate layer 220 and the pixel-defining film 119.

Although a configuration of the third sub-pixel SP3 has been mainly described in more detail, the description of the third sub-pixel SP3 may also be applied to the first sub-pixel SP1 and/or the second sub-pixel SP2 in the same or substantially the same manner, and thus, redundant description thereof will not be repeated. Because a corresponding pixel circuit is located in each of the first sub-pixel SP1 to the third sub-pixel SP3, the pixel circuit located in the first sub-pixel SP1 may be referred to as a first pixel circuit, the pixel circuit located in the second sub-pixel SP2 may be referred to as a second pixel circuit, and the pixel circuit located in the third sub-pixel SP3 may be referred to as a third pixel circuit.

Similarly, the driving transistor T1 included in the first sub-pixel SP1 may be referred to as a first driving transistor, the driving transistor T1 included in the second sub-pixel SP2 may be referred to as a second driving transistor, and the driving transistor T1 included in the third sub-pixel SP3 may be referred to as a third driving transistor.

The first capacitor Cst and the second capacitor Chold included in the first sub-pixel SP1 may be respectively referred to as a 1-1^{th} capacitor and a 1-2^{th} capacitor. The first capacitor and the second capacitor included in the second sub-pixel SP2 may be respectively referred to as a 2-1^{th} capacitor and a 2-2^{th} capacitor. The first capacitor and the second capacitor included in the third sub-pixel SP3 may be respectively referred to as a 3-1^{th} capacitor and a 3-2^{th} capacitor.

In the display apparatus according to the present embodiment, the driving voltage line PL may be located at (e.g., in or on) the lower metal layer 1100, and may extend in the first direction (e.g., the x-axis direction). A part of the driving voltage line PL may function as the fourth capacitor electrode CE4 of the second capacitor Chold. Accordingly, because only the second buffer layer 113 is located between the fourth capacitor electrode CE4 of the second capacitor Chold and the third capacitor electrode CE3 provided as the semiconductor layer 1200, a vertical distance between the third capacitor electrode CE3 and the fourth capacitor electrode CE4 may be decreased.

For example, when the fourth capacitor electrode CE4 is formed at (e.g., in or on) the second conductive layer 1400, a vertical distance between the third capacitor electrode CE3 and the fourth capacitor electrode CE4 may be about 6400 Å. However, when the fourth capacitor electrode CE4 is formed as the lower metal layer 1100 according to the present embodiment, a vertical distance between the third capacitor electrode CE3 and the fourth capacitor electrode CE4 may be about 2300 Å.

Accordingly, an area occupied by the second capacitor Chold may be reduced, and a high capacitance may be maintained.

Also, in the present embodiment, because the driving voltage line PL is located at (e.g., in or on) the lower metal layer 1100, a driving voltage line may not be located at (e.g., in or on) the second conductive layer 1400 or one driving voltage line may be located across a plurality of sub-pixels, and thus, a degree of integration may be increased. In this case, the additional line WL may be used as a driving voltage line.

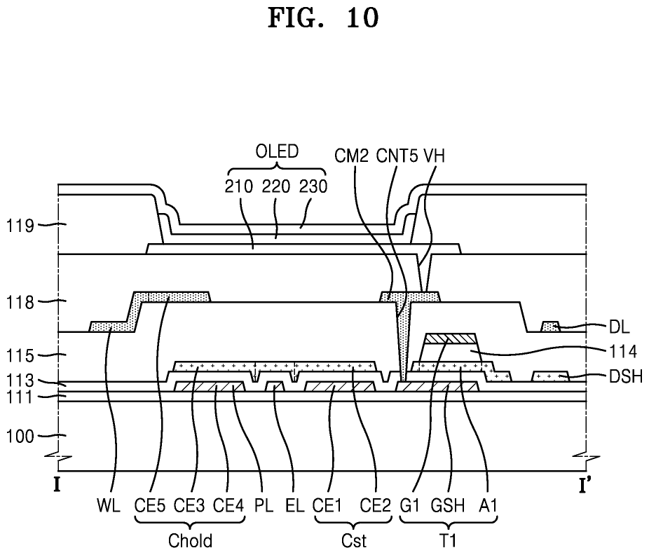

FIG. 10 is a cross-sectional view schematically illustrating a portion of a display apparatus, according to an embodiment. In FIG. 10, the same references numerals are used as those in FIG. 9 to denote the same or substantially the same members, and thus, redundant description thereof may not be repeated.

Referring to FIG. 10, the display apparatus may include the substrate 100, the pixel circuit located on the substrate 100 and including transistors including the driving transistor T1, the first capacitor Cst, and the second capacitor Chold, and the organic light emitting diode OLED as a display element connected to the pixel circuit.

The first capacitor Cst may include the first capacitor electrode CE1, and the second capacitor electrode CE2 overlapping with the first capacitor electrode CE1. The first capacitor electrode CE1 may be provided as the lower metal layer 1100 (e.g., see FIG. 5), and the second capacitor electrode CE2 may be provided as the semiconductor layer 1200 (e.g., see FIG. 6).

The second capacitor Chold may include the third capacitor electrode CE3, and the fourth capacitor electrode CE4 overlapping with the third capacitor electrode CE3. The third capacitor electrode CE3 may be provided as the semiconductor layer 1200 (e.g., see FIG. 6), and the fourth capacitor electrode CE4 may be provided as the lower metal layer 1100 (e.g., see FIG. 5). The third capacitor electrode CE3 may be integrally provided with the second capacitor electrode CE2.

In the present embodiment, the second capacitor Chold may further include the fifth capacitor electrode CE5. The fifth capacitor electrode CE5 may be located on the interlayer insulating layer 115. The fifth capacitor electrode CE5 may overlap with the third capacitor electrode CE and/or the fourth capacitor electrode CE4. The fifth capacitor electrode CE5 may be provided as the second conductive layer 1400 (e.g., see FIG. 8). The fifth capacitor electrode CE5 may be provided as a part of the additional line WL.

In some embodiments, the second capacitor Chold included in some sub-pixels may not include the fifth capacitor electrode CE5, and the second capacitor Chold included in some sub-pixels may include the fifth capacitor electrode CE5. As another example, an area of the fifth capacitor electrode CE5 may be variously modified according to the sub-pixels. Accordingly, a capacitance of the second capacitor Chold may vary according to the sub-pixels.

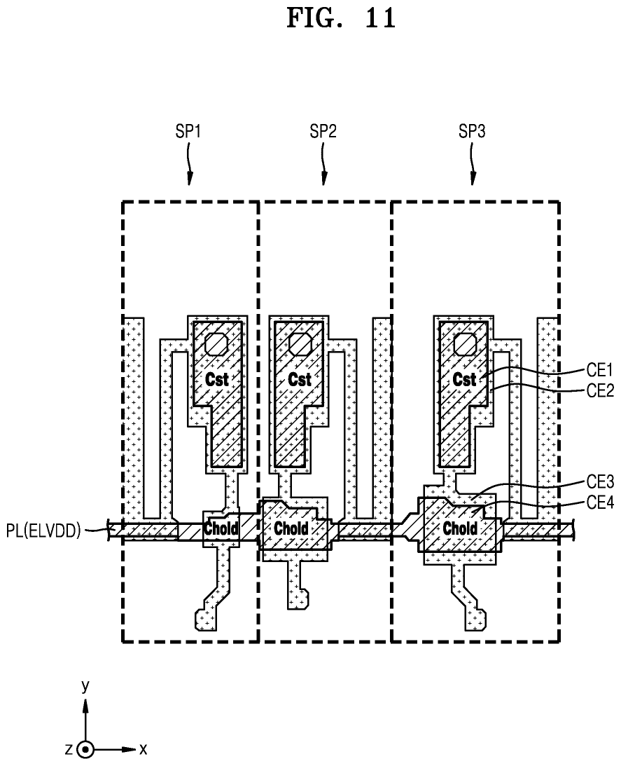

FIG. 11 is a layout view schematically illustrating some elements of sub-pixels included in a display apparatus, according to an embodiment. In more detail, FIG. 11 illustrates the first capacitor Cst and the second capacitor Chold included in each sub-pixel.

Referring to FIG. 11, each of the first sub-pixel SP1, the second sub-pixel SP2, and the third sub-pixel SP3 may include a corresponding first capacitor Cst and a corresponding second capacitor Chold. The first capacitor Cst includes the first capacitor electrode CE1 and the second capacitor electrode CE2 overlapping with each other, and the second capacitor Chold includes the third capacitor electrode CE3 and the fourth capacitor electrode CE4.

The first capacitor electrode CE1 and the fourth capacitor electrode CE4 may be provided as the lower conductive layer 1100 (e.g., see FIG. 5). The first capacitor electrode CE1 may be provided in an isolated shape. The fourth capacitor electrode CE4 may be provided as a part of the driving voltage line PL that extends in the first direction (e.g., the x-axis direction).

The second capacitor electrode CE2 and the third capacitor electrode CE3 may be provided as the semiconductor layer 1200 (e.g., see FIG. 6). The second capacitor electrode CE2 and the third capacitor electrode CE3 may be integrally provided with each other.

A capacitance of the first capacitor Cst may be determined by an overlapping area between the first capacitor electrode CE1 and the second capacitor electrode CE2. A capacitance of the second capacitor Chold may be determined by an overlapping area between the third capacitor electrode CE3 and the fourth capacitor electrode CE4.

The overlapping area between the first capacitor electrode CE1 and the second capacitor electrode CE2 may be greater than the overlapping area between the third capacitor electrode CE3 and the fourth capacitor electrode CE4. In other words, a magnitude of a capacitance of the first capacitor Cst may be greater than a magnitude of a capacitance of the second capacitor Chold.

In the present embodiment, a capacitance of the 1-2^{th} capacitor that is the second capacitor Chold included in the first sub-pixel SP1 may be different from a capacitance of the 2-2^{th} capacitor that is the second capacitor Chold included in the second sub-pixel SP2 and/or a capacitance of the 3-2^{th} capacitor that is the second capacitor Chold included in the third sub-pixel SP3.

For example, as shown in FIG. 11, a capacitance of the 1-2^{th} capacitor may be less than a capacitance of the 2-2^{th} capacitor, and a capacitance of the 2-2^{th} capacitor may be less than a capacitance of the 3-2^{th} capacitor. However, the present disclosure is not limited thereto, and various modifications may be made as needed or desired. For example, a capacitance of the 1-2^{th} capacitor may be greater than a capacitance of the 2-2^{th} capacitor, and a capacitance of the 2-2^{th} capacitor may be greater than a capacitance of the 3-2^{th} capacitor.

The wirings included in the second conductive layer 1400 (e.g., see FIG. 8) may be differently provided in each of the first to third sub-pixels SP1, SP2, and SP3. For example, the vertical initialization line VLb may be located at a boundary between the first sub-pixel SP1 and the second sub-pixel SP2, and the additional line WL may be located in the third sub-pixel SP3. Accordingly, each of the first to third sub-pixels SP1, SP2, and SP3 may have a different parasitic capacitance. Because capacitance values of the second capacitors Chold in the first to third sub-pixels SP1, SP2, and SP3 may be different from each other in an embodiment, the effect of a parasitic capacitance may be minimized or reduced.

According to one or more embodiments of the present disclosure as described above, a display apparatus in which a degree of integration may be increased may be provided, and a high-quality image may be displayed. However, the spirit and scope of the present disclosure are not limited by the above aspects and features.

Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display apparatus comprising:
a substrate;
a driving transistor over the substrate, and comprising a semiconductor layer comprising a driving active area;
a driving voltage line between the substrate and the semiconductor layer, and extending in a first direction;
a first capacitor comprising a first capacitor electrode at the same layer as that of the driving voltage line, and a second capacitor electrode at the same layer as that of the semiconductor layer; and
a second capacitor comprising a third capacitor electrode at the same layer as that of the semiconductor layer, and a fourth capacitor electrode as a part of the driving voltage line.

2. The display apparatus of claim 1, wherein an overlapping area between the first capacitor electrode and the second capacitor electrode is greater than an overlapping area between the third capacitor electrode and the fourth capacitor electrode.

3. The display apparatus of claim 1, wherein the second capacitor electrode and the third capacitor electrode are integral with each other.

4. The display apparatus of claim 1, further comprising:
an interlayer insulating layer covering the driving transistor; and
a first connection electrode on the interlayer insulating layer, and connecting the first capacitor electrode to a gate electrode of the driving transistor,
wherein the first connection electrode is connected to the first capacitor electrode through a contact hole in an opening of the second capacitor electrode.

5. The display apparatus of claim 1, wherein the semiconductor layer comprises an oxide semiconductor material.

6. The display apparatus of claim 1, further comprising a driving shield layer at the same layer as that of the driving voltage line, and overlapping with the driving active area.

7. The display apparatus of claim 6, further comprising:
an interlayer insulating layer covering the driving transistor; and
a second connection electrode on the interlayer insulating layer, and connecting the driving shield layer to the second capacitor electrode.

8. The display apparatus of claim 1, further comprising:
a first scan line at the same layer as that of the driving voltage line, and extending in the first direction; and
a switching transistor electrically connected to the first scan line, the switching transistor comprising:
a lower switching gate electrode;
a semiconductor layer comprising a switching active area; and
an upper switching gate electrode,
wherein the lower switching gate electrode, the switching active area, and the upper switching gate electrode are sequentially stacked, and
wherein the lower switching gate electrode is a part of the first scan line.

9. The display apparatus of claim 1, further comprising:
an interlayer insulating layer covering the driving transistor; and
a data line and an additional line on the interlayer insulating layer, and extending in a second direction crossing the first direction.

10. The display apparatus of claim 9, wherein the second capacitor further comprises a fifth capacitor electrode as a part of the additional line.

11. A display apparatus comprising:
a substrate;
a first sub-pixel on the substrate, and comprising a first pixel circuit comprising:
a first driving transistor comprising a semiconductor layer;
a 1-1^{th} capacitor; and
a 1-2^{th} capacitor;
a second sub-pixel on the substrate, and comprising a second pixel circuit comprising:
a second driving transistor;
a 2-1^{th} capacitor; and
a 2-2^{th} capacitor; and
a driving voltage line between the substrate and the semiconductor layer, the driving voltage line extending in a first direction, and electrically connected to the first sub-pixel and the second sub-pixel,
wherein the 1-2^{th} capacitor comprises:
a 1-3^{th} capacitor electrode at the same layer as that of the semiconductor layer; and
a 1-4^{th} capacitor electrode as a part of the driving voltage line, and
wherein the 2-2^{th} capacitor comprises:
a 2-3^{th} capacitor electrode at the same layer as that of the semiconductor layer; and
a 2-4^{th} capacitor electrode as a part of the driving voltage line.

12. The display apparatus of claim 11, wherein a capacitance of the 1-2^{th} capacitor is different from a capacitance of the 2-2^{th} capacitor.

13. The display apparatus of claim 11, wherein one electrode of the 1-1^{th} capacitor is integral with one electrode of the 1-2^{th} capacitor.

14. The display apparatus of claim 11, wherein a driving gate electrode of the first driving transistor is electrically connected to one electrode of the 1-1^{th} capacitor.

15. The display apparatus of claim 11, further comprising a driving shield layer at the same layer as that of the driving voltage line, and overlapping with the first driving transistor.

16. The display apparatus of claim 15, wherein the driving shield layer is electrically connected to one electrode of the 1-1^{th} capacitor.

17. The display apparatus of claim 11, further comprising a first initialization line and a second initialization line at the same layer as that of the driving voltage line, wherein the first initialization line is connected to the first sub-pixel, and wherein the second initialization line is connected to the second sub-pixel.

18. The display apparatus of claim 17, further comprising:
an interlayer insulating layer covering the first driving transistor and the second driving transistor; and
a vertical initialization line on the interlayer insulating layer, and extending in a second direction crossing the first direction,
wherein the vertical initialization line is connected to one of the first initialization line or the second initialization line through a contact hole.

19. The display apparatus of claim 11, further comprising:
a third sub-pixel on the substrate, and comprising a third pixel circuit comprising:
a third driving transistor;
a 3-1^{th} capacitor; and
a 3-2^{th} capacitor;
an interlayer insulating layer covering the first driving transistor, the second driving transistor, and the third driving transistor; and
an additional line on the interlayer insulating layer, and extending in a second direction crossing the first direction,
wherein one of the additional line corresponds to the first sub-pixel, the second sub-pixel, and the third sub-pixel.

20. The display apparatus of claim 19, wherein the 3-2^{th} capacitor comprises a fifth capacitor electrode as a part of the additional line.
